(19) United States
(12) Patent Application Publication
(10) Pub. No.: US 2019/0123224 A1
(43) Pub. Date: Apr. 25, 2019

(54) FLEXIBLE SOLAR CELL CHIP PACKAGING BOX

(71) Applicant: MIASOLE EQUIPMENT INTEGRATION (FUJIAN) CO., LTD., Quanzhou (CN)

(72) Inventors: Hongxia SUN, Quanzhou (CN); Chao HU, Quanzhou (CN); Yi SHU, Quanzhou (CN); Pengjian ZHU, Quanzhou (CN); Fan CHEN, Quanzhou (CN); Deng PAN, Quanzhou (CN); Bo ZHOU, Quanzhou (CN)

(21) Appl. No.: 16/115,714

(22) Filed: Aug. 29, 2018

(30) Foreign Application Priority Data
Oct. 25, 2017 (CN) 201721384663.3

(51) Int. Cl. H01L 31/048; H01L 31/0392; H01L 31/0203

(52) U.S. Cl. CPC H01L 31/048; H01L 31/0203; H01L 31/03926

(57) ABSTRACT

A flexible solar cell chip packaging box includes a housing body and a housing cover. The housing body includes a bottom wall and a first side wall which is perpendicularly and fixedly connected to the bottom wall, the first side wall and the bottom wall enclose a receiving chamber provided with an opening, and the first side wall is provided with a first groove. The housing cover includes a top wall and a second side wall which is perpendicularly and fixedly connected to the top wall, the top wall is covered on the opening, and the second side wall is sleeved on the outside of the first side wall.

### CROSS-REFERENCE TO RELATED APPLICATION

This application claims priority to CN application No. 201721384663.3, filed Oct. 25, 2017, the entire content of which is incorporated herein by reference.

### TECHNICAL FIELD

The embodiment of the present application relates to, but is not limited to, the technical field of packaging boxes, and in particular relates to, but is not limited to, a flexible solar cell chip packaging box.

### BACKGROUND

Battery packaging, especially flexible solar cell chip packaging, has been widely used in photovoltaic power generation field. The packaging integrity of flexible solar cell chip directly affects the quality of flexible solar cell chip.

The existing flexible solar cell chip packaging technology is such that the flexible solar cell chip is only covered by plastic film and then is put into a vacuum polyester film packaging bag. On one hand, this method is prone to be influenced by human, and improper manipulation by operators can easily cause the corner to be folded or bended or the like, therefore damaging the flexible solar cell chip. On the other hand, this technology has the limitation of not being able to completely fix the position of the flexible solar cell chip, which easily causes the flexible cell chip to move during transportation, therefore causing problems such as corner folding, bending, deformation, etc.

### SUMMARY

The following is an overview of the subject matter described in detail herein.

A flexible solar cell chip packaging box according to an embodiment of the application includes:

a housing body including a bottom wall and a first side wall which is perpendicularly and fixedly connected to the bottom wall, the first side wall and the bottom wall enclosing a receiving chamber provided with an opening, the first side wall being provided with a first groove;

a housing cover including a top wall and a second side wall which is perpendicularly and fixedly connected to the top wall, the top wall being covered on the opening, the second side wall being sleeved on the outside of the first side wall.

In an exemplary embodiment, the first groove extends from a top end to a bottom end of the first side wall.

In an exemplary embodiment, the first side wall is provided with a plurality of first grooves.

In an exemplary embodiment, the plurality of first grooves may be divided into at least one group, and each group includes two first grooves arranged oppositely.

In an exemplary embodiment, the housing body includes two opposite first side walls, and the two first grooves in each group are separately arranged on the two opposite first side walls.

In an exemplary embodiment, the two opposite first side walls are provided with two groups of the first grooves.

In an exemplary embodiment, the housing body has a rectangular cuboid shape, and the first groove is arranged on the first side wall which extends in the length direction of the rectangular cuboid.

In an exemplary embodiment, the edge of the first groove is an arc-shaped edge.

In an exemplary embodiment, the edge of the first groove is provided with a protective sleeve.

In an exemplary embodiment, the second side wall is provided with a second groove.

In an exemplary embodiment, when the second side wall is sleeved on the outside of the first side wall, the second groove and the first groove are not aligned with each other.

In an exemplary embodiment, the second groove extends from a bottom end to a top end of the second side wall.

In an exemplary embodiment, the second side wall is provided with a plurality of the second grooves.

In an exemplary embodiment, the plurality of second grooves may be divided into at least one group, and each group includes two second grooves arranged oppositely.

In an exemplary embodiment, the housing cover has a rectangular cuboid shape and the second groove is arranged on the second side wall which extends in the length direction of the rectangular cuboid.

In an exemplary embodiment, the flexible solar cell chip packaging box further includes a first shielding sheet to shield the first groove. Two sides of the first groove are provided with first rails, and two side edges of the first shielding sheet are inserted into the first rails.

In an exemplary embodiment, the flexible solar cell chip packaging box further includes a second shielding sheet to shield the second groove. Two sides of the second groove are provided with second rails, and two side edges of the second shielding sheet are inserted into the second rails.

In an exemplary embodiment, an inner side of the second side wall is provided with a protrusion, or an outer side of the first side wall is provided with a protrusion, or the inner side of the second side wall and the outer side of the first side wall are provided with protrusions.

In an exemplary embodiment, the bottom wall is provided with a cushioning pad, or an inner side of the first side wall is provided with a cushioning pad, or the bottom wall and the inner side of the first side wall are provided with cushioning pads.

In an exemplary embodiment, the bottom wall and the first side wall are adhesively fixed, or the top wall and the second side wall are adhesively fixed, or the bottom wall and the first side wall are adhesively fixed and the top wall and the second side wall are adhesively fixed.

Other aspects will become apparent after reading and understanding the brief description of the drawings and the embodiments of the present application.

### BRIEF DESCRIPTION OF DRAWINGS

FIG. 1 is a schematic isometric view of a housing body of a flexible solar cell chip packaging box according to an embodiment of the application.

FIG. 2 is a schematic isometric view of a housing cover of a flexible solar cell chip packaging box according to an embodiment of the application.

FIG. 3 is a schematic exploded structural view of a housing body assembly of a flexible solar cell chip packaging box according to an embodiment of the application.

FIG. 4 is a schematic structural view of the housing body in FIG. 3.

FIG. 5 is an enlarged schematic view of the structure of part A of FIG. 4.

FIG. 6 is a schematic exploded structural view of a housing cover assembly of a flexible solar cell chip packaging box according to an embodiment of the application.

FIG. 7 is a schematic structural view of the housing cover in FIG. 6.

FIG. 8 is an enlarged schematic view of the structure of part B of FIG. 7.

FIG. 9 is a schematic exploded structural view of a flexible solar cell chip packaging box according to an embodiment of the application.

### REFERENCE SIGNS IN THE DRAWINGS

10 - housing body
11 - bottom wall
12 - first side wall
13 - receiving chamber
14 - opening
15 - first groove
16 - first shielding sheet
17 - first rail
18 - cushion pad
19 - protrusion
20 - housing cover
21 - top wall
22 - second side wall
23 - second groove
24 - second shielding sheet
25 - second rail
26 - cushion pad
27 - protrusion

### DETAILED DESCRIPTION

Embodiments of the present application are described in detail below, and examples of embodiments are shown in the accompanying drawings, throughout which the same or similar reference signs denote the same or similar elements or elements having the same or similar functions. The embodiments described below with reference to the accompanying drawings are exemplary, merely used to explain the present application and cannot be construed as limiting the present application.

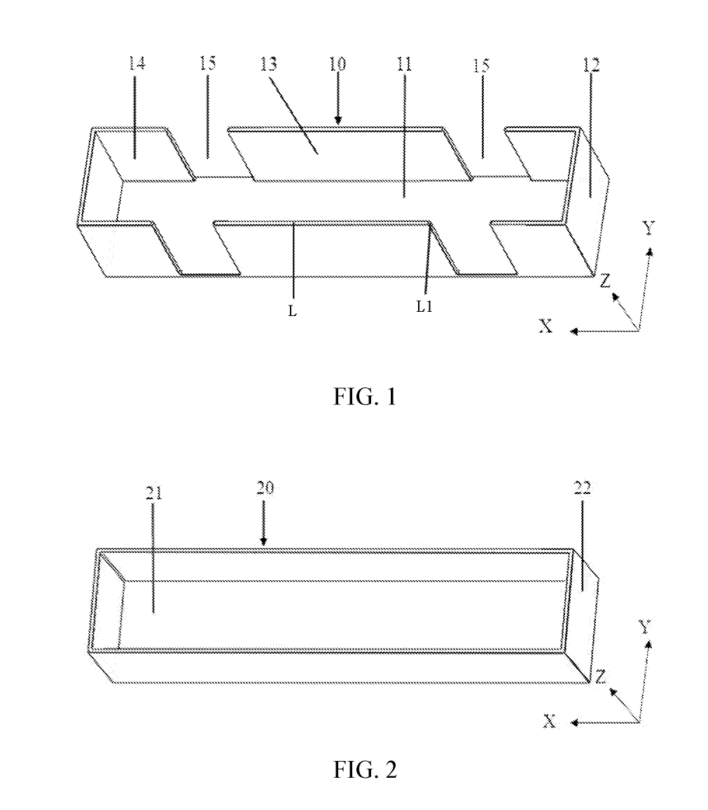

As shown in FIGS. 1 and 2, a flexible solar cell chip packaging box according to an embodiment of the application includes a housing body 10 and a housing cover 20.

As shown in FIG. 1, the housing body 10 includes a bottom wall 11 and a first side wall 12 which is perpendicularly and fixedly connected to the bottom wall 11. The first side wall 12 and the bottom wall 11 enclose a receiving chamber 13 provided with an opening 14. The first side wall 12 is provided with a first groove 15. As shown in FIG. 2, the housing cover 20 includes a top wall 21 and a second side wall 22 is perpendicularly and fixedly connected to the top wall 21. The opening 14 is covered by the top wall 21, and the second side wall 22 is sleeved on the outside of the first side wall 12.

It will be understood by those skilled in the art that the number of the first side wall and the second side wall described above may be one or more, depending on the specific shape of the packaging box. Both the housing body 10 and the housing cover 20 can be made of plastic to reduce the weight of the entire packaging box.

When the flexible solar cell chip packaging box according to the embodiment of the application is in use, a flexible solar cell chip is placed into the receiving chamber 13 through the opening 14, and then the housing body 10 is covered by the housing cover 20, so that the flexible solar cell chip can be maximally protected during transportation of the flexible solar cell chip. Thus the problems such as corner folding, bending and deformation are avoided, and the wear and tear of the flexible solar cell chip during transportation is reduced. When the flexible solar cell chip needs to be removed from the packaging box, the housing cover 20 can be removed, and the flexible solar cell chip can be connected with the hand(s) of an operator or a pick-up device (for example, the flexible solar cell chip can be pinched or clamped manually or by a pick-up device) through the first groove 15. The flexible solar cell chip can be grabbed and taken out through the opening 14. With the arrangement of the first groove 15, the packaging box is very convenient to use and the problems such as corner folding, bending and deformation caused when removing the flexible solar cell chip are avoided.

The first side wall 12 and the second side wall 22 may be interference fitted, transition fitted, or clearance fitted when the housing cover 20 is covered on the housing body 10. Since both the housing body 10 and the housing cover 20 are made of plastic, when the first side wall 12 and the second side wall 22 are interference fitted, the packaging box can be fastened more tightly due to the elasticity of the housing body 10 and the housing cover 20, avoiding accidental opening of the packaging box and avoiding falling of the flexible solar cell chip. The clearance fit or the transition fit is convenient for workers to open the packaging box and improve the efficiency of picking up the flexible solar cell chip. In this case, in order to prevent the housing cover 20 from accidentally opening, a locking mechanism can be arranged between the housing cover 20 and the housing body 10. For example, positioning holes can be formed in the second side wall 22 of the housing cover 20 and the first side wall 12 of the housing body 10, and then a positioning pin can be inserted through the positioning holes to lock the housing cover 20 and the housing body 10 during transportation. With such arrangement, it is also convenient to open the housing cover 20, take out and place the flexible solar cell chip.

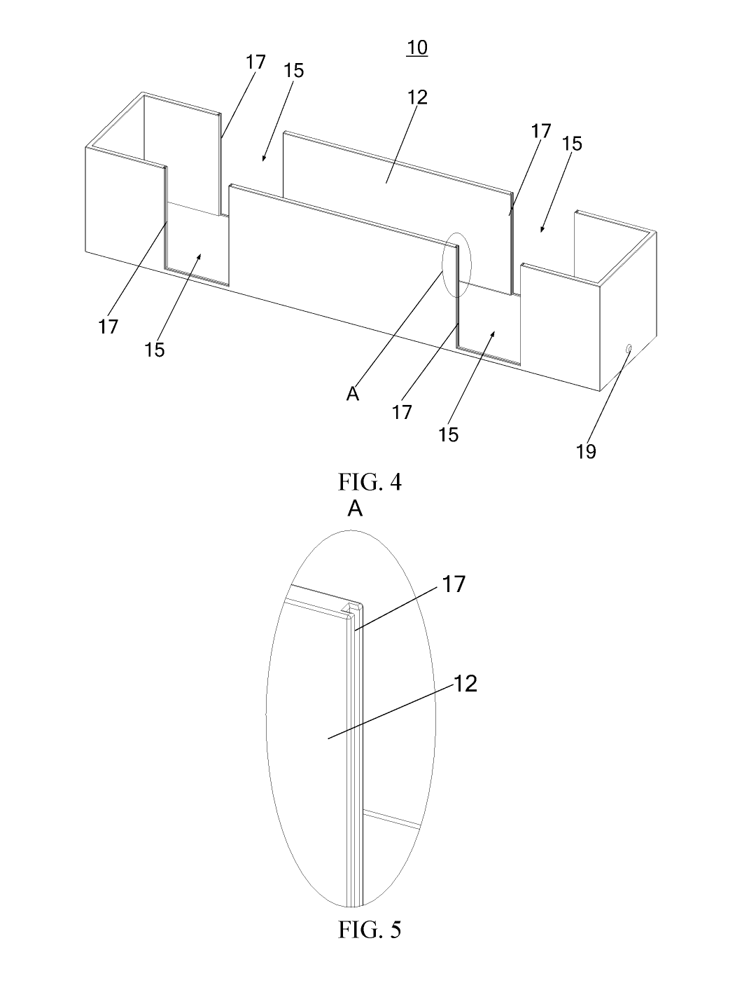

When grabbing the flexible solar cell chip through the first groove 15 and taking out the flexible solar cell chip through the opening 14, in order to prevent the edge of the first groove 15 from damaging the flexible solar cell chip, the edge of the first groove 15 is configured as an arc-shaped edge, that is, the edge of the first groove 15 is rounded (see FIG. 5), to prevent the right angle edge from damaging the flexible solar cell chip, and to prevent the right angle edge of the first groove 15 from scratching hands when grabbing the flexible solar cell chip through the first groove 15 and taking out and placing the flexible solar cell chip through the opening 14.

Alternatively, a protective sleeve can be wrapped around the edge of the first groove 15. The protective sleeve can be made of rubber material to prevent the flexible solar cell chip from being squeezed and bending when contacting the edge of the first groove 15. Besides, the protective sleeve can also protect hands and prevent hands from being scratched by the first groove 15 in the processes of taking out and placing the flexible solar cell chip.

When the operator needs to pick up the flexible solar cell chip, normally, the packaging box is placed right side up, that is, the housing cover 20 is located above the housing body 10. However, sometimes, it is possible that the packaging box is placed upside down. In the case that the packaging box is upside down, the operator is apt to incorrectly operate and open the packaging box from the side of the housing body 10. In order to solve this problem, in the embodiments shown in FIGS. 6, 7 and 9, a second groove 23 may be formed in the second side wall 22. When the second side wall 22 is sleeved on the outside of the first side wall 12, the second groove 23 and the first groove 15 are not aligned with each other. In this case, if the flexible solar cell chip is integrally located in the housing cover 20 upside down, the flexible solar cell chip can be grabbed at the second groove 23 of the housing cover 20 manually or by a pick-up device and taken out from the housing cover 20. Thus there is no need to place the packaging box entirely right side up, avoiding that the flexible solar cell chip can be taken out from the housing body 10 only after multiple operations, thereby making the packaging box more convenience to use.

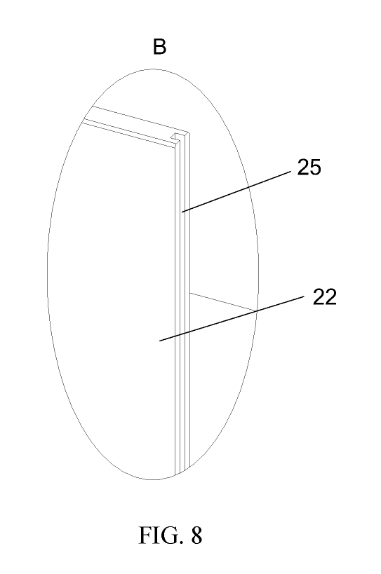

The edge of the second groove 23 can also be configured as an arc-shaped edge, i.e., the edge of the second groove 23 is rounded (see FIG. 8). It is also possible to wrap a protective sleeve around the edge of the second groove 23. The protective sleeve can be made of rubber material to prevent the flexible solar cell chip from being squeezed and bending when contacting the edge of the second groove 23. The protective sleeve can also protect hand and prevent the hand from being scratched by the second groove 23 in the processes of taking out and placing the flexible solar cell chip.

In order to prevent an improper operation of opening the packaging box from the side of the housing body 10 which causes the flexible solar cell chip to be integrally placed upside down in the housing cover 20, an indication mark may be provided on the packaging box to prevent an improper operation caused by the inversion of the packaging box. For example, an arrow may be provided on the second side wall 22 of the housing cover 20 to indicate the up-down direction of the packaging box.

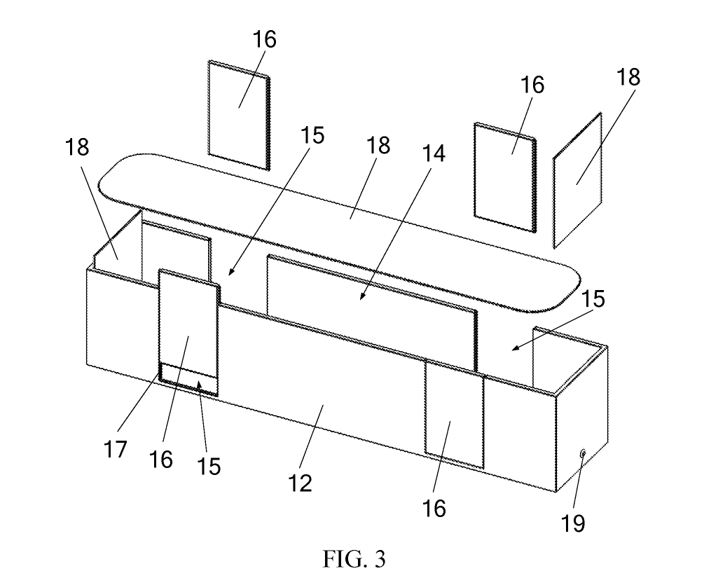

In one embodiment, as shown in FIG. 3, a first shielding sheet 16 may be provided at the first groove 15 for shielding the first groove 15. When there is no need to take out the flexible solar cell chip, the first groove 15 can be shielded to avoid accidental damage to the flexible solar cell chip, and when the flexible solar cell chip needs to be taken out, the first shielding sheet 16 is removed to facilitate taking out the flexible solar cell chip.

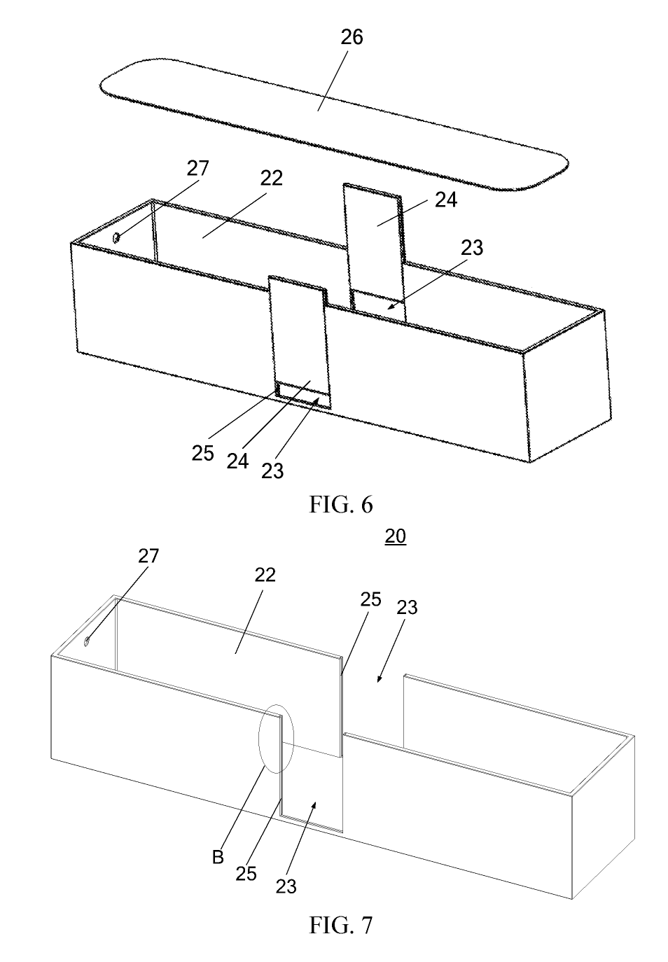

As shown in FIGS. 4 and 5, two sides of the first groove 15 may be provided with first rails 17, and the two side edges of the first shielding sheet 16 are inserted into the first rails 17 and may slide along the first rails 17. Likewise, as shown in FIG. 6, a second shielding sheet 24 may be provided at the second groove 23, and the second shielding sheet 24 is used to shield the second groove 23. As shown in FIGS. 7 and 8, second rails 25 can be provided on both sides of the second groove 23, and two side edges of the second shielding sheet 24 are inserted into the second rails 25 and may slide along the second rails 25.

Those skilled in the art will understand that the size and shape of the housing body 10 and the housing cover 20 can be actually designed according to the size and shape of the flexible solar cell chip. For example, if the flexible solar cell chip is circular in shape, both the housing body 10 and the housing cover 20 can be configured to have a circular shape correspondingly.

In the actual production process, the flexible solar cell chips can be a rectangular shape (including a square shape). In an embodiment, the housing body 10 can be a rectangular cuboid shape (including a cubic shape), and correspondingly, the housing cover 20 can be a rectangular cuboid shape (including a cubic shape). In a specific example, the shape of the bottom wall 11 is rectangular, and the number of the first side walls 12 is four. The four first side walls 12 are perpendicularly and fixedly connected to the four sides of the bottom wall 11, and the adjacent first side walls 12 are all fixedly connected. The shape of the top wall 21 can be rectangular, and the number of the second side walls 22 is four. The four second side walls 22 are perpendicularly and fixedly connected to the four sides of the top wall 21, and the adjacent second side walls 22 are all fixedly connected.

In one embodiment, the packaging box needs to contain a flexible solar cell chip (e.g., the flexible solar cell chip is CIGS, C: Cu, I: In, G: Ga, S: Se) with a length of 312 mm, a width of 56.95 mm, and a thickness of 0.23 mm. The housing body 10 can be designed to be 323 mm in length, 67.5 mm in width, and 68 mm in height as needed, as shown in FIG. 1 where the X direction is the length direction, the Y direction is the width direction, and the Z direction is the height direction. Accordingly, the housing cover 20 is designed to have a length of 331 mm, a width of 75.5 mm, and a height of 68 mm, as shown in FIG. 2 where the X direction is the length direction, the Y direction is the width direction, and the Z direction is the height direction. The wall thicknesses of the housing body 10 and the housing cover 20 may be 3 mm. With respect to a packaging box of this size, 177 pieces of the flexible solar cell chips of the above size can be placed in the receiving chamber 13.

In order to facilitate a user to take out the flexible solar cell chip, the first groove 15 may extend from the top end to the bottom end of the first side wall 12 (the top end and the bottom end here are determined based on the direction in FIG. 1). The flexible solar cell chips located at the lowest layer and the uppermost layer in the receiving chamber 13 can be grabbed easily through the first groove 15, and making it more convenience to take out the flexible solar cell chips. Likewise, the second groove 23 may extend from the bottom end to the top end of the second side wall 22.

In an embodiment, the first side wall 12 is provided with a plurality of first grooves 15, and when picking up the flexible solar cell chip, the flexible solar cell chip can be grabbed at multiple positions through the plurality of first grooves 15 to facilitate the removal.

The plurality of first grooves 15 can be divided into at least one group and each group includes two opposite first grooves 15, so that when the flexible solar cell chip is grabbed through the first grooves 15 for removal, the thumb and forefinger (or middle finger) of the hand can grab (e.g., clamp) both sides of the flexible solar cell chip through the two opposite first grooves 15. It will be understood that both sides of the flexible solar cell chip can also be grabbed by other device through the two opposite first grooves 15 to take out the flexible solar cell chip.

The housing body 10 (e.g., a rectangular cuboid shaped housing body 10) may include two opposite first side walls 12, and the two first grooves 15 in each group are separately arranged on the two opposite first side walls 12.

The two opposite first side walls 12 may be provided with two groups of first grooves, i.e., two first grooves 15 may be formed on each of the two opposite first side walls 12. The two first grooves 15 on one first side wall 12 may be arranged to separately correspond to the two first grooves 15 on the other opposite first side wall 12. Thus, when grabbing the flexible solar cell chip through the first grooves 15 for removal, two hands can cooperate with each other to grab two ends of the flexible solar cell chip so as to facilitate removing and prevent deformation of the solar cell chip during removing. It should be understood that two opposite first side walls 12 may also be provided with one or more than three groups of first grooves, and the number of the first grooves may be set according to the length of the flexible solar cell chip.

In one embodiment, as shown in FIG. 1, the housing body 10 has a rectangular cuboid shape, and the first groove 15 is provided on the first side wall 12 which extends in the length direction of the rectangular cuboid (i.e., the X direction in FIG. 1), so that both ends of the solar cell chip along the length direction can be grabbed when being pick up.

The size of the first groove 15 can be designed according to actual needs. In an embodiment shown in FIG. 1, four first grooves 15 are arranged on two first side walls 12 extending along the length direction. The distance between the left first groove 15 and the left edge of the first side wall 12 may be 50 mm, the distance between the right first groove 15 and the right edge of the first side wall 12 may be 50 mm, and the length of each first groove 15 in the X direction may be 40 mm.

Likewise, the second side wall 22 may be provided with a plurality of second grooves 23. The position, number, size and the like of the second grooves 23 may be the same as or different from that of the first grooves. In the embodiments shown in FIGS. 6 and 7, the housing cover 20 has a rectangular cuboid shape, and two second grooves 23 are arranged on the two second side walls 22 which extend in the length direction of the rectangular cuboid. The two second grooves 23 are arranged oppositely, so that when the flexible solar cell chip is integrally located upside down in the housing cover 20, the solar cell chip can be grabbed through the two second grooves 23 and be picked up.

In order to increase the tightness of the housing cover 20 covered on the housing body 10, a protrusion may be provided on the inner side of the second side wall 22, or a protrusion may be provided on the outer side of the first side wall 12, or protrusions may be separately provided on the inner side of the second side wall 22 and the outer side of the first side wall 12. The protrusion can increase the fitting force between the first side wall 12 and the second side wall 22 to prevent the housing cover 20 from loosening during transportation which may cause the flexible solar cell chip to fall off, causing unnecessary losses. In the embodiments shown in FIGS. 3 and 4, the outer side of the first side wall 12 of the housing body 10 is provided with a protrusion 19. In the embodiments shown in FIGS. 6 and 7, a protrusion 27 is provided on the inner side of the second side wall 22 of the housing cover 20.

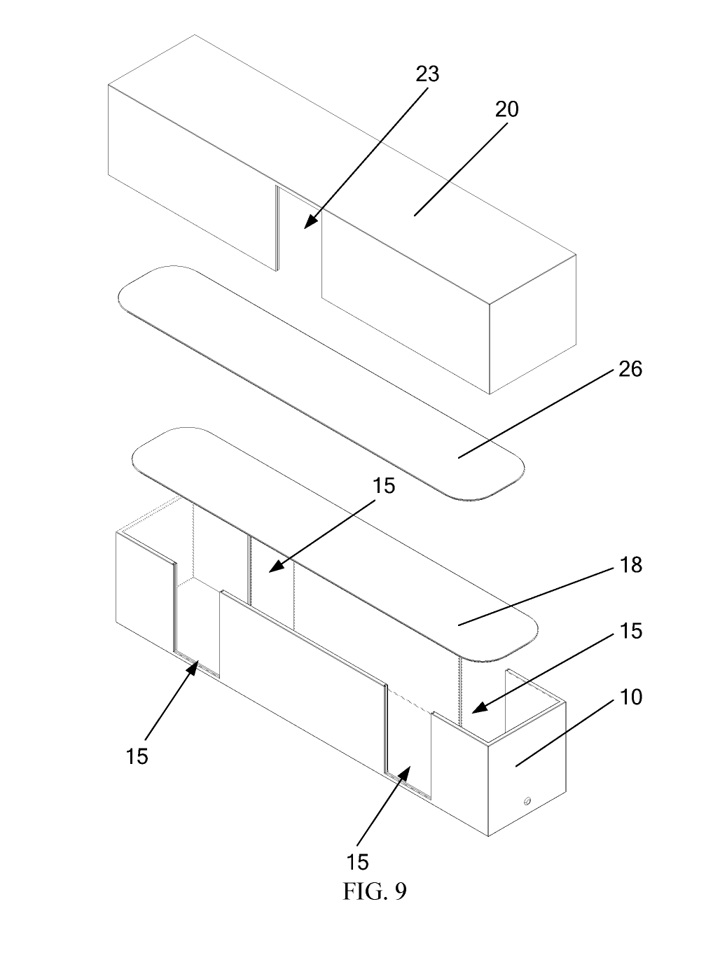

A cushion pad may be provided on the bottom wall 11, or a cushion pad may be provided on the first side wall 12 of the housing body 10, or cushion pads may be separately provided on the bottom wall 11 and the first side wall 12 of the housing body 10. The cushion pad can prevent the flexible solar cell chip from being damaged due to falling and other reasons during transportation of the packaging box, thus cushion the flexible solar cell chip. In the embodiment shown in FIG. 3, the bottom wall 11 and the two opposite first side walls 12 are provided with cushioning pads 18. In the embodiment shown in FIG. 9, a cushion pad 18 is provided on the bottom wall 11. In an embodiment, the cushion pad 18 may be a layer of soft plastic film, or a rubber sheet, or a sponge sheet, or the like.

Likewise, the top wall 21 of the housing cover 20 may be provided with a cushion pad. The cushion pad can cushion the flexible solar cell chip to prevent the flexible solar cell chip from being damaged. In the embodiments shown in FIGS. 6 and 9, the top wall 21 of the housing cover 20 is provided with a cushion pad 26. In an embodiment, the cushion pad 26 may be a layer of soft plastic film, or a rubber sheet, or a sponge sheet, or the like.

In order to reduce the overall weight of the packaging box and thus reduce the transportation load, in an embodiment, the packaging box is made of acrylic plastic material. The packaging box made of such material has a smooth and clean surface without any depression or projection. In addition, in a packaging box made of such material, there is no fragment drop, no color difference and no deformation.

During processing, hot melt adhesive may be used to bond the bottom wall 11 and the first side wall 12 together and bond the top wall 21 and the second side wall 22 together. Those skilled in the art will understand that the bottom wall 11 and the first side wall 12 as well as the top wall 21 and the second side wall 22 may also be fixedly connected by other means such as welding. Alternatively, the bottom wall 11 and the first side wall 12 as well as the top wall 21 and the second side wall 22 may be integrally formed by injection molding or the like.

In order to prevent the edge of the packaging box from bumping against the flexible solar cell chip and to increase the aesthetics of the packaging box, all the edges L of the housing body 10 and the housing cover 20 are rounded (the radius of the rounded portion is 0.3 mm), and all the edge corners L1 are rounded (the radius of the rounded portion is 1 mm).

In the description of this application, the term “a plurality of” refers to two or more than two.

The structure, features, and effects of the embodiment of the present application have been described above in detail according to the embodiments shown in the drawings. The above embodiments are merely the exemplary embodiments of the present application, but the present application is not limited to the implementation scope as shown in the drawings. Changes based on the conception of embodiments of the present application, or equivalent embodiments with equivalent modifications are within the protection scope of the present application without depart from the spirit covered by the description and the drawings.

What we claim is:

1. A flexible solar cell chip packaging box, comprising:
a housing body comprising a bottom wall and a first side wall which is perpendicularly and fixedly connected to the bottom wall, the first side wall and the bottom wall enclosing a receiving chamber provided with an opening, the first side wall being provided with a first groove;
a housing cover comprising a top wall and a second side wall which is perpendicularly and fixedly connected to the top wall, the top wall being covered on the opening, the second side wall being sleeved on the outside of the first side wall.

2. The flexible solar cell chip packaging box according to claim 1, wherein the first groove extends from a top end to a bottom end of the first side wall.

3. The flexible solar cell chip packaging box according to claim 1, wherein the first side wall is provided with a plurality of first grooves.

4. The flexible solar cell chip packaging box according to claim 3, wherein the plurality of first grooves can be divided into at least one group, and each group comprises two first grooves arranged oppositely.

5. The flexible solar cell chip packaging box according to claim 4, wherein the housing body comprises two opposite first side walls, and the two first grooves in each group are separately arranged on the two opposite first side walls.

6. The flexible solar cell chip packaging box according to claim 5, wherein the two opposite first side walls are provided with two groups of the first grooves.

7. The flexible solar cell chip packaging box according to claim 1, wherein the housing body has a rectangular cuboid shape, and the first groove is arranged on the first side wall which extends in the length direction of the rectangular cuboid.

8. The flexible solar cell chip packaging box according to claim 1, wherein the edge of the first groove is an arc-shaped edge.

9. The flexible solar cell chip packaging box according to claim 1, wherein the edge of the first groove is provided with a protective sleeve.

10. The flexible solar cell chip packaging box according to claim 1, wherein the packaging box further comprises a first shielding sheet to shield the first groove, two sides of the first groove are provided with first rails, and two side edges of the first shielding sheet are inserted into the first rails.

11. The flexible solar cell chip packaging box according to claim 1, wherein the second side wall is provided with a second groove.

12. The flexible solar cell chip packaging box according to claim 11, wherein when the second side wall is sleeved on the outside of the first side wall, the second groove and the first groove are not aligned with each other.

13. The flexible solar cell chip package box according to claim 11, wherein the second groove extends from a bottom end to a top end of the second side wall.

14. The flexible solar cell chip packaging box according to claim 11, wherein the second side wall is provided with a plurality of the second grooves.

15. The flexible solar cell chip packaging box according to claim 14, wherein the plurality of second grooves can be divided into at least one group, and each group comprises two second grooves arranged oppositely.

16. The flexible solar cell chip packaging box according to claim 11, wherein the housing cover has a rectangular cuboid shape and the second groove is arranged on the second side wall which extends in the length direction of the rectangular cuboid.

17. The flexible solar cell chip packaging box according to claim 11, wherein the packaging box further comprises a second shielding sheet to shield the second groove, two sides of the second groove are provided with second rails, and two side edges of the second shielding sheet are inserted into the second rails.

18. The flexible solar cell chip packaging box according to claim 1, wherein an inner side of the second side wall is provided with a protrusion, or an outer side of the first side wall is provided with a protrusion, or the inner side of the second side wall and the outer side of the first side wall are provided with protrusions.

19. The flexible solar cell chip packaging box according to claim 1, wherein the bottom wall is provided with a cushioning pad, or an inner side of the first side wall is provided with a cushioning pad, or the bottom wall and the inner side of the first side wall are provided with cushioning pads.

20. The flexible solar cell chip packaging box according to claim 1, wherein the bottom wall and the first side wall are adhesively fixed, or the top wall and the second side wall are adhesively fixed, or the bottom wall and the first side wall are adhesively fixed and the top wall and the second side wall are adhesively fixed.
